(19) United States
(12) Patent Application Publication
(10) Pub. No.: US 2009/0201639 A1
(43) Pub. Date: Aug. 13, 2009

(54) CHASSIS OF PORTABLE ELECTRONIC APPARATUS

(75) Inventors: Feng-Ku WANG, Taipei (TW); Chih-Kai YANG, Taipei (TW); Wei-Hsin WU, Taipei (TW)

Correspondence Address: Workman Nydegger;1000 Eagle Gate Tower, 60 East South Temple, Salt Lake City, UT, 84111, US

(73) Assignee: INVENTEC CORPORATION, Taipei (TW)

(21) Appl. No.: 12/029,692

(22) Filed: Feb. 12, 2008

(51) Int. Cl. G06F 1/20; H05K 7/20; G06F 1/16

(52) U.S. Cl. 361/679.54; 361/690

(57) ABSTRACT

A chassis of a portable electronic apparatus includes a heat sink assembly disposed therein and carries a keyboard on the top. The chassis has an air inlet and an air outlet on a first surface on the side opposite to the keyboard, which are respectively corresponding to an intake end and an exhaust end of the heat sink assembly. The air outlet extends from the first surface to a second surface connected to the first surface, and the second surface has an opening for disposing communication connectors, so as to adequately the heat sink assembly and the communication connectors.

### BACKGROUND OF THE INVENTION

1. Field of the Invention

The present invention relates to a chassis structure of an electronic apparatus, and more particularly to a chassis of a portable electronic apparatus.

2. Related Art

As the efficiency of various electronic products has been increasingly enhanced, the heat sink problem is getting serious accordingly, among which the heat sink problem for the portable electronic apparatus is most severe. As for the portable electronic apparatus such as notebook computers and handheld computers, in order to maintain the light and portable characteristics, the design of the chassis is based on the principle of being light, thin, short, and small. In comparison, the inner space of the chassis for the portable electronic apparatus is quite limited, such that the electronic components within the chassis should be intensively arranged. Therefore, the heat generated after a long-time operation of the electronic components is easily accumulated within the chassis of the portable electronic apparatus, such that the temperature in the whole portable electronic apparatus is dramatically increased rapidly in a short time. Therefore, if the heat inside the chassis of the portable electronic apparatus cannot be dissipated in time, and the electronic components keep operating at a high temperature, the normal operation of the portable electronic apparatus is definitely influenced, and even the electronic components are damaged due to being overheated.

Generally, many output/input communication connectors for connecting peripheral hardware devices are arranged at the side of the chassis for the host of the notebook computer. However, as the users' increasing demand for more peripheral hardware devices of the notebook computer, there are more and more communication connectors arranged on the side of the chassis. On the other hand, the bottom of the chassis for the host of the notebook computer is opened with a plurality of air inlets for dissipating heats, and the side of the chassis for the host of the notebook computer is opened with a plurality of air outlets for dissipating heats. A heat sink is disposed within the chassis of the host, which can intake the air from the outside (at the bottom of the chassis) into the chassis through the air inlets, and exhaust the heated air out of the chassis (through the side of the chassis) through the air outlets after a heat exchange process with the air. However, the positions for opening the air inlets at the side of the chassis may have a conflict with the positions for opening the communication connectors. The heat sink hole opened at the side of the chassis for the host may occupy the space originally planned for allocating the communication connectors. As a result, other positions on the chassis of the host should be found for allocating the communication connectors.

### SUMMARY OF THE INVENTION

In view of the problem in the conventional art that the positions for opening the heat sink holes of the notebook computer occupies the space for allocating the communication connectors at the side of the chassis, the present invention is directed to a chassis of a portable electronic apparatus, which is capable of improving the space allocation of the portable electronic apparatus.

In order to achieve the above objective, the present invention provides a chassis of a portable electronic apparatus, including a heat sink assembly disposed therein and carrying a keyboard. The heat sink assembly has an intake end and an exhaust end, and the heat sink assembly intakes air through the intake end and exhausts the air through the exhaust end. The chassis has a first surface on the side opposite to the keyboard, and the first surface has at least one air inlet corresponding to the intake end of the heat sink assembly and at least one air outlet corresponding to the exhaust end of the heat sink assembly. The air outlet extends from the first surface of the chassis to a second surface connected to the first surface, and the second surface is opened with a communication connector for allocating a communication connector, such that the communication connector is exposed out of the chassis through the communication connector opening. In a preferred embodiment of the present invention, the first surface is located at the bottom of the chassis, and the second surface is located on the chassis and connected to the side of the bottom of the chassis.

The efficacy of the present invention lies in, the air outlet for the heat sink assembly to exhaust the air is located at the bottom of the chassis and extends to the lower edge of the side of the chassis, such that the side of the chassis is opened with a communication connector for allocating the communication connector, so as to improve the flexibility for the space allocation of the portable electronic apparatus, and thus further offering more space for allocating the communication connectors.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1 is a schematic perspective view of a portable electronic apparatus in the present invention;

FIG. 2 is a schematic cross-sectional view of a portable electronic apparatus in the present invention; and

FIG. 3 is a schematic view of a direction of an air flow in FIG. 2.

### DETAILED DESCRIPTION OF THE INVENTION

In order to make the aforementioned and other objectives, features, and advantages of the present invention be more comprehensible, the present invention is described in detail below through preferred embodiments accompanied with figures.

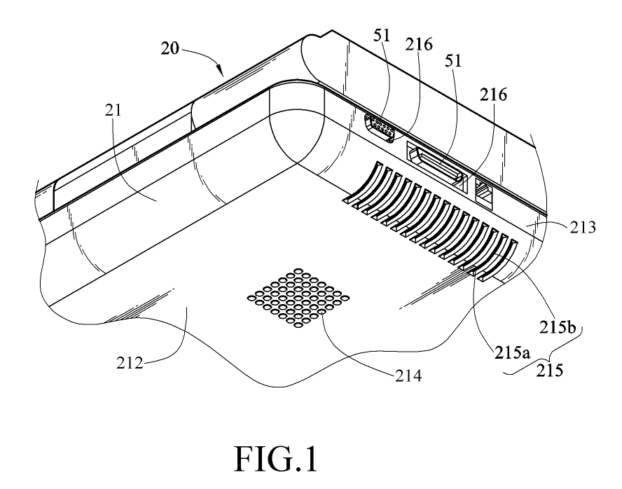

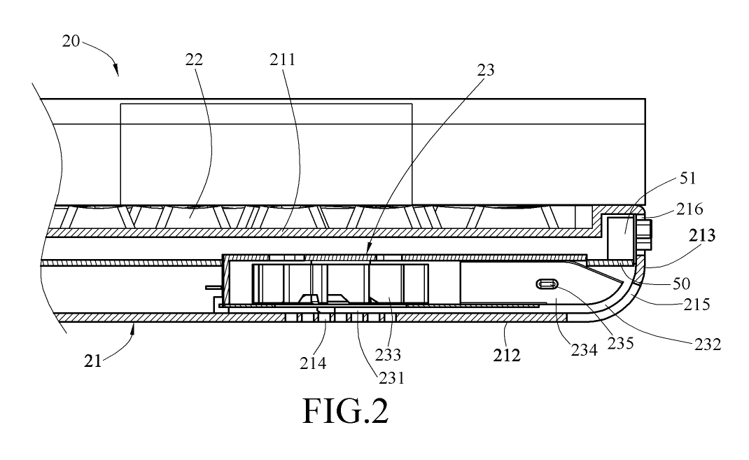

Referring to FIGS. 1 and 2, a chassis 21 of a portable electronic apparatus in the present invention is shown, which is used for accommodating the host of the portable electronic apparatus 20 and carrying a keyboard 22. In the detailed description of the present invention, the portable electronic apparatus 20 is, but not limited to, a notebook computer or a handheld computer. The chassis 21 of the portable electronic apparatus 20 includes a circuit board 50 and a heat sink assembly 23 disposed therein. The circuit board 50 is, but not limited to, a motherboard within the host, and the heat sink assembly 23 is used to dissipate heats for the circuit board 50. A plurality of communication connectors 51 are arranged at the edge of the circuit board 50, which are used for connecting the host of the portable electronic apparatus 20 to the extended peripheral hardware devices.

The heat sink assembly 23 has an intake end 231 to intake air and an exhaust end 232 to exhaust the air, and the heat sink assembly 23 is formed by a fan 233, a heat sink fin set 234, and a heat pipe 235. The heat pipe 235 is embedded into the heat sink fin set 234, takes away the heat energy of the heat source on the circuit board 50 by means of heat conduction, and conducts the heat energy of the heat source onto the heat sink fin set 234. The fan 233 is used for blowing an air flow towards the heat sink fin set 234 and the heat pipe 235, and forcing the air to be convected within the chassis 21, such that the heat energy on the heat sink fin set 234 and the heat pipe 235 is conducted to the air flow through heat exchange, and thus being taken away by means of heat exchange, heat conduction, and heat convection.

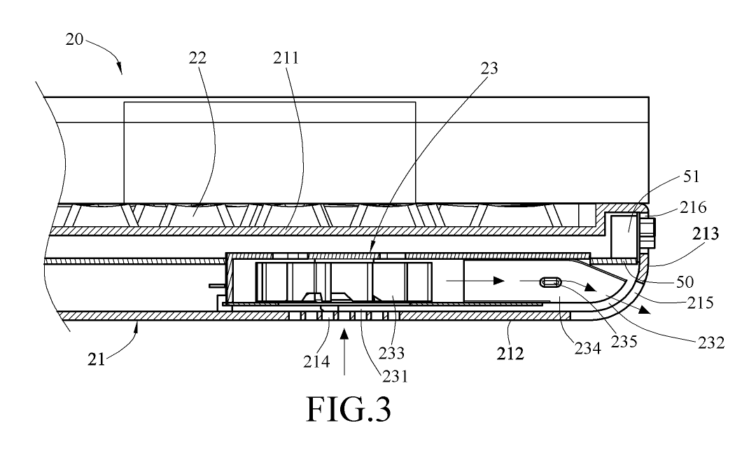

Referring to FIGS. 2 and 3, the chassis 21 of the portable electronic apparatus 20 provides an appropriate protection and support to the electronic components (the circuit board 50) and the heat sink assembly 23 within the host. The chassis 21 has a plate 211 on the top, and the keyboard 22 of the portable electronic apparatus 20 is fixed on the plate 211. The chassis 21 has a first surface 212 on the side opposite to the keyboard 22, and the edge of the first surface 212 is connected to a second surface 213. The first surface 212 is located at the bottom of the chassis 21, and the second surface 213 is located on the side of the chassis 21 and connected to the edge of the plate 211 through the first surface 212. The circuit board 50 is fixed between the first surface 212 and the plate 211, and located on the inner side of the second surface 213 for the chassis 21. The first surface 212 of the chassis 21 has a plurality of air inlets 214 and a plurality of air outlets 215. The air inlets 214 are corresponding to the intake end 231 (the fan 233) of the heat sink assembly 23, and the air outlets 215 are corresponding to the exhaust end 232 (the heat sink fin set 234) of the heat sink assembly 23. Therefore, the fan 233 of the heat sink assembly 23 may smoothly intake the air into the chassis 21 through the air inlets 214, so as to generate the air flow for blowing towards the heat sink fin set 234 and the heat pipe 235, and then, after passing through the heat sink fin set 234 and the heat pipe 235, the air flow is smoothly exhausted out of the chassis 21 via the air outlets 215. The opening of the air outlets 215 is extended from the first surface 212 of the chassis 21 to reach the second surface 213, and each air outlet 215 has a flat segment 215a and a bent segment 215b. The flat segment 215a of the air outlet 215 is located on the first surface 212 of the chassis 21, i.e., the bottom of the chassis 21. The bent segment 215b of the air outlet 215 is extended from the first surface 212 of the chassis 21 to the lower edge of the second surface 213, i.e., a part of the bent segment 215b is located at the bottom of the chassis 21, and the other part is located at the side of the chassis 21. Therefore, a plurality of communication connector openings 216 may be opened at the second surface 213 of the chassis 21 opposite to the keyboard 22, and each communication connector opening 216 is corresponding to the communication connector 51 on the circuit board 50, such that the communication connector 51 is exposed out of the chassis 21 through the communication connector opening 216.

The air outlets 215 in the present invention, provided for the heat sink assembly 23 to exhaust the air, are located at the bottom of the chassis 21 for the portable electronic apparatus 20, and extended to the lower edge of the side of the chassis 21. Moreover, the side of the chassis 21 may be opened with heat sink holes, or also may be opened with the communication connector openings 216 for allocating the communication connectors 51 of the circuit board 50, so as to improve the flexibility for the space allocation of the portable electronic apparatus 20, and thus further providing more space for allocating the communication connectors 51.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A chassis of a portable electronic apparatus, comprising a heat sink assembly disposed therein and carrying a keyboard, wherein the heat sink assembly has an intake end and an exhaust end, the chassis has a first surface on the side opposite to the keyboard, and the first surface has at least one air inlet corresponding to the intake end and at least one air outlet corresponding to the exhaust end.

2. The chassis of the portable electronic apparatus as claimed in claim 1, wherein the air outlet extends from the first surface to a second surface connected to the first surface.

3. The chassis of the portable electronic apparatus as claimed in claim 2, wherein the second surface has at least one communication connector opening.

4. The chassis of the portable electronic apparatus as claimed in claim 2, wherein the air outlet has a flat segment and a bent segment, the flat segment is located on the first surface, and the bent segment extends from the first surface to the second surface.
